(19) United States
(12) Patent Application Publication
(10) Pub. No.: US 2008/0014703 A1
(43) Pub. Date: Jan. 17, 2008

(54) Method of fabricating semiconductor integrated circuit device and semiconductor integrated circuit device manufactured using the same

(76) Inventor: Jeong-min Choi, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 11/822,614

(22) Filed: Jul. 9, 2007

(30) Foreign Application Priority Data
Jul. 10, 2006 (KR) 10-2006-0064444

(51) Int. Cl. H01L 21/336

(52) U.S. Cl. 438/299

(57) ABSTRACT

A method of fabricating a semiconductor integrated circuit device may include forming a first gate insulating film and a first gate electrode on a first region of a substrate, and forming a second gate insulating film and a second gate electrode on which a plurality of recesses are formed on a second region of the substrate, forming first and second source/drain regions in the substrate, the first and second source/drain regions being aligned with the first and second gate electrodes, respectively, and forming a first metal silicide film and a second metal silicide film on the first and second source/drain regions and the second gate electrode, respectively, wherein the second metal silicide film is thicker than the first metal silicide film and a cross-sectional shape of the second metal silicide film is wave shaped.

### BACKGROUND OF THE INVENTION

1. Field of the Invention

The present invention relates to a method of fabricating a semiconductor integrated circuit device and a semiconductor integrated circuit device manufactured using such a method. More particularly, the present invention relates to a semiconductor integrated circuit device including a semiconductor device having improved characteristics and a method of fabricating the same.

2. Description of the Related Art

As semiconductor devices are becoming highly integrated, their design rules are rapidly decreasing and their operating speeds are increasing. Therefore, efforts are being made to reduce the sheet resistance and the contact resistance of a gate, source, and drain of a semiconductor device. In order to reduce resistance, silicide having a very low specific resistance may be formed. Metal silicide provided in a semiconductor device may serve to reduce the contact resistance of an active region and a gate electrode, and may be formed of metal compound including metal and silicon, such as titanium, silicide (TiSi₂), tungsten silicide (WSi₂), cobalt silicide (CoSi₂) or nickel silicide (NiSi₂).

Transistors of various sizes may be formed on a semiconductor substrate.

For example, a transistor formed in one region, e.g., a part of a core region, perimeter region and/or peripheral region (“core/peri region”), may require less resistance than a transistor formed in another region. It is possible to reduce resistance by increasing a thickness of a metal silicide. However, e.g., while increasing the thickness of the metal silicide may be a solution for reducing a resistance of the transistors formed on the semiconductor substrate, increasing the thickness of metal silicide provided on, e.g., a small transistor may give rise to other problems.

For example, a transistor formed in a cell region may be small in size and a source/drain region may be small in depth. When a metal silicide is formed with a large thickness on the thin source/drain region, leakage current may occur in the source/drain region.

More particularly, an isolation region may be formed at a boundary region between an active region and an isolation region, and a small groove may appear between the active region and the isolation region during a cleaning process. As a result of such a groove, the surface area of the exposed substrate at the boundary between the active region and the isolation region may be larger than that of other areas. Therefore, if the substrate including such a groove is subjected to a metal silicide reaction, a silicide reaction may occur more at the boundary region between the active region and the isolation region than at other regions. As a result, a thickness of the metal silicide at the boundary region between the active region and the isolation region may be increased, and leakage current may be more likely to occur at the boundary region between the active region and the isolation region.

Accordingly, the thickness of the metal silicide should be flexibly controlled according to regions of the substrate in consideration of characteristics of the transistors, e.g., the desired/designed resistance value and/or size of the transistor.

### SUMMARY OF THE INVENTION

The present invention is therefore directed to a method of fabricating a semiconductor integrated circuit device and a semiconductor integrated circuit device, which substantially overcomes one or more of the problems due to the limitations and disadvantages of the related art.

It is therefore a feature of an embodiment of the present invention to provide a method of fabricating a semiconductor integrated circuit device including a semiconductor device having improved characteristics.

It is therefore a separate feature of an embodiment of the present invention to provide a semiconductor integrated circuit device including a semiconductor device having improved characteristics.

At least one of the above and other features and advantages of the present invention may be realized by providing a method of fabricating a semiconductor integrated circuit device, the method including forming a first gate insulating film and a first gate electrode on a first region of a substrate, and forming a second gate insulating film and a second gate electrode on which a plurality of recesses are formed on a second region of the substrate, forming first and second source/drain regions in the substrate, the first and second source/drain regions being aligned with the first and second gate electrodes, respectively, and forming a first metal silicide film and a second metal silicide film on the first and second source/drain regions and the second gate electrode, respectively, wherein the second metal silicide film may be thicker than the first metal silicide film and a cross-sectional shape of the second metal silicide film is wave shaped.

Forming the second gate electrode may include forming a second gate electrode pattern on the second gate insulating film, forming a hard mask on the substrate, patterning a top surface of the second gate electrode pattern using the hard mask as an etching mask to form the second gate electrode including the plurality of recesses, and removing the hard mask. The hard mask may include SiON.

Defining the first region and the second region may include forming an isolation region in the substrate, and an interval between a lower boundary of the first metal silicide and a lower boundary of the source/drain region is about 400 Å or more at a region where the isolation region contacts the first source/drain region.

The method may include forming a third metal silicide film on a surface of the first gate electrode while forming the first metal silicide film and the second metal silicide film. Forming the first metal silicide film and the second metal silicide film may include forming a metal film on the substrate and thermally treating the substrate.

At least one of the above and other features and advantages of the present invention may be separately realized by providing a semiconductor integrated circuit device, including a first transistor on a first region of a semiconductor substrate, the first transistor including a first gate insulating film, a first gate electrode, first source/drain regions aligned with the first gate electrode, and a first metal silicide film on a surface of the first source/drain region, the first metal silicide film having a first thickness, and a second transistor on a second region of the semiconductor substrate, the second transistor including a second gate insulating film, a second gate electrode, second source/drain regions aligned with the second gate electrode, and a second metal silicide film on a surface of the second gate electrode, the second metal silicide film having a second thickness that is larger than the first thickness and having a cross-sectional shape that is wave shaped.

A top surface of the second metal silicide film may include a plurality of recesses. The second thickness of the second metal silicide film may be larger than a depth of the recesses. An interval between the plurality of recesses may be about 400 Å or more. The plurality of recesses may be arranged along a direction along which the second gate electrode extends.

The device may include an isolation region at one side of the first source/drain region, wherein at a region where the isolation region contacts the first source/drain region, an interval between a lower boundary of the first metal silicide film and a lower boundary of the respective first source/drain region is about 400 Å or more. The first region may be a cell region, and the second region may be a core/peri region.

The second transistor may be a device having less resistance than the first transistor. The first and second silicide films may include at least one of titanium (Ti), tungsten (W), cobalt (Co), and nickel (Ni). A third metal silicide film may be disposed on a surface of the first gate electrode. A fourth metal silicide film may be disposed on a surface of the second source/drain regions.

The third metal silicide film may have a uniform or substantially uniform thickness. The device may further include an isolation region at one side of each of the first and second source/drain regions, wherein the thickness of the first metal silicide film and a thickness of the fourth metal silicide film is larger at a region where the respective isolation region contacts the first and second source/drain region regions, respectively, than at a region of the first and second source/drain region closer to the first and second gate electrodes, respectively.

At least one of the above and other features and advantages of the present invention may be separately realized by providing a semiconductor integrated circuit device, including a first transistor on a first defined region of a substrate, the first transistor including first source/drain regions, a first gate insulating film and a first gate electrode, the first gate electrode having a substantially flat top surface, a second transistor on a second defined region of the substrate, the second transistor including second source/drain regions, a second gate insulating film and a second gate electrode, the second gate electrode having a plurality recesses on a top surface thereof, at least one of a first metal silicide film on the first gate electrode and a second metal silicide film on the first and second source/drain regions, the first metal silicide film and the second metal silicide film having a substantially flat top surface, and a third metal silicide film on the second gate electrode, the third metal silicide film having a plurality of recesses on a top surface thereof corresponding to the plurality of recesses on the top surface of the second gate insulating film.

The third metal silicide film may have a greater thickness than the first metal silicide film and/or the second metal silicide film.

Features of the present invention are not limited to those mentioned above, and other features of the present invention will be apparently understood by those skilled in the art through the following description.

Other aspects of the present invention will be included in the detailed description of the invention and the drawings.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a flow chart of stages of a method of fabricating a semiconductor integrated circuit device according to an exemplary embodiment of the invention; and

FIGS. 2 to 8 illustrate cross-sectional views of sequential stages in the method of fabricating a semiconductor integrated circuit device according to the exemplary embodiment of the invention.

### DETAILED DESCRIPTION OF THE INVENTION

Korean Patent Application No. 10-2006-0064444 filed on Jul. 10, 2006 in the Korean Intellectual Property Office, and entitled: “Method of Fabricating Semiconductor Integrated Circuit Device and Semiconductor Integrated Circuit Device Manufactured Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

Also, terminology used herein is for the purpose of describing particular exemplary embodiments only and is not intended to limit the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Like reference numerals refer to like elements throughout the specification.

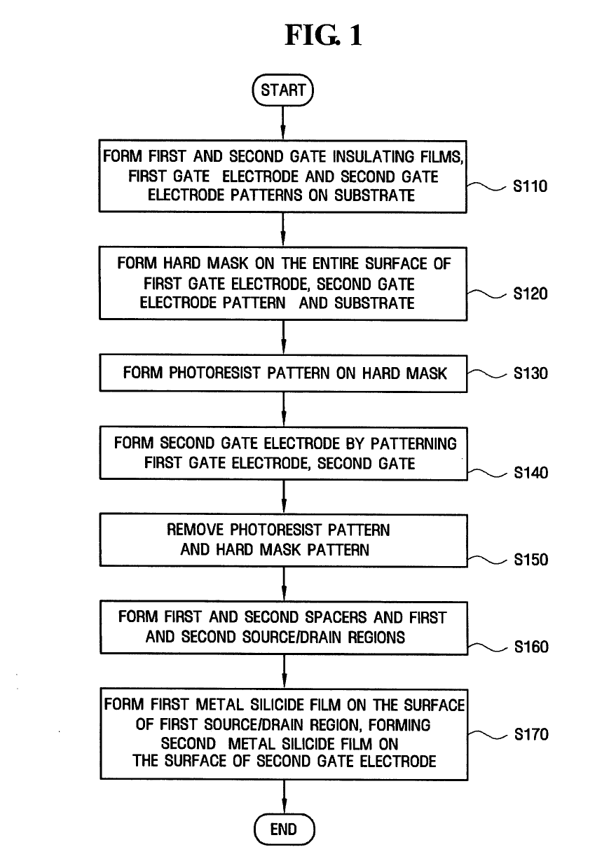

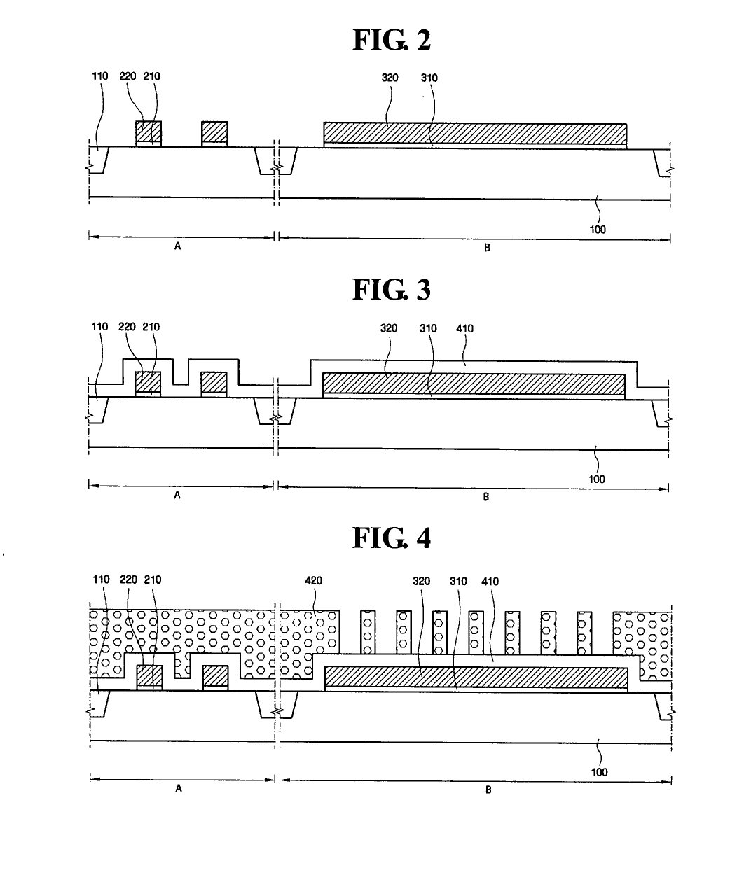

An exemplary method of fabricating a semiconductor integrated circuit device according to an embodiment of the invention will be described with reference to FIGS. 1 to 8. More particularly, FIG. 1 illustrates a flow chart of stages of a method of fabricating a semiconductor integrated circuit device according to an exemplary embodiment of the invention, and FIGS. 2 to 8 illustrate cross-sectional views of sequential stages in the method of fabricating a semiconductor integrated circuit device according to the exemplary embodiment of the invention.

While describing the exemplary method of fabricating a semiconductor integrated circuit device, detailed description of process(es) that can be formed according to process steps known to those skilled in the art will be omitted so as to avoid straying from the subject matter of the present invention.

With reference to FIGS. 1 and 2, first and second gate insulating films 210 and 310 may be formed on a substrate 100 (S110). A first gate electrode 220 and a second gate electrode pattern 320 may be respectively formed on the first and second gate insulating films 210 and 310 on the substrate 100 (S110).

More particularly, as shown in FIG. 2, the substrate 100 may first be divided into different regions. For example, the substrate 100 may be divided into a first region A and a second region B. The second region B may correspond to a relatively lower resistance region than the first region A. For example, the first region A may correspond to one of a cell region or a core/peri region, and the second region B may correspond to the other of a cell region and a core/peri region. More particularly, e.g., the first region may correspond to the cell region and the higher resistance region, and the second region B may correspond to the core/peri region and the lower resistance region.

Further, e.g., the substrate 100 may be divided into an active region and an inactive region by an isolation film 110, e.g., an STI (Shallow Trench Isolation) or an FOX (Field Oxide). A substrate formed of one or more semiconductor materials, e.g., Si, Ge, SiGe, GaP, GaAs, SiC, SiGeC, InAs and InP, and SOI (Silicon On Insulator) may be used as the substrate 100.

After dividing the substrate 100 into different regions, the first gate insulating film 210 and the first gate electrode 220 may be formed on a top surface of the substrate 100 in the first region A, and the second gate insulating film 310 and a second gate electrode pattern 320 may be formed on the top surface of the substrate 100 in the second region B.

The first and second gate insulating films 210 and 310 may include, e.g., silicon oxide film formed by, e.g., thermally oxidizing the substrate 100, SiON, GeₓO_{y}N_{z}, GeₓSi_{y}O_{z}, a high dielectric material, mixtures thereof, and/or a laminate thereof, in which they are sequentially laminated. The high dielectric material may include, e.g., HfO₂, ZrO₂, Al₂O₃, Ta₂O₅, hafnium silicate, zirconium silicate, and/or mixtures thereof.

The first gate electrode 220 and the second gate electrode pattern 320 may be, e.g., conductors, and may include, e.g., polysilicon that is doped with impurities. In cases employing polysilicon that is doped with impurities, e.g., if the polysilicon is N-type polysilicon, the polysilicon may be formed first, and then doped with N-type impurities by ion injection, or may be doped with N-type impurities in-situ during deposition of the polysilicon. In such cases, e.g., phosphorus (P) or arsenic (As), etc., may be used as the N-type impurities.

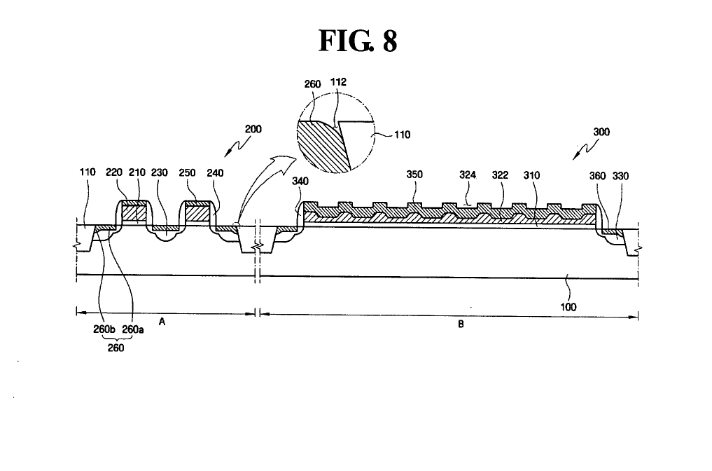

In some embodiments of the invention, the first gate electrode 220 and the second gate electrode pattern 320 may be formed of a same material, while in other embodiments of the invention, the first gate electrode 220 and the second gate electrode pattern 320 may be formed of different materials in accordance with characteristics of first and second transistors 200, 300 (shown in FIG. 8) to be formed.

Next, with reference to FIGS. 1 and 3, a hard mask 410 may be formed on a surface, e.g., an entire surface, of the first gate electrode 220, the second gate electrode pattern 320, and the substrate 100 (S120).

The hard mask 410 may be formed of, e.g., SiON. The thickness of the hard mask 410 may be equal to and/or set in a range of about 500 Å to about 1000 Å. The hard mask 410 may be used as an etching mask during a subsequent photolithography process, and may also function as an antireflection film.

Next, with reference to FIGS. 1 to 4, a photoresist pattern 420 may be formed on the hard mask 410 (S130).

The photoresist pattern 420 may be patterned so as to expose portions of a top surface of the hard mask 410. In some embodiments of the invention including a plurality of the exposed portions, the exposed portions may be formed in a direction along which the second gate electrode pattern 320 extends, e.g., along a length of the second gate electrode pattern 320. The photoresist pattern 420 may be formed by forming a photoresist layer (not shown) on the top surface of the substrate 100, e.g., the entire top surface of the substrate 100, and then patterning the photoresist layer to form the photoresist pattern 420 using, e.g., an optical mask, to expose portion(s) of the top surface of the hard mask 410.

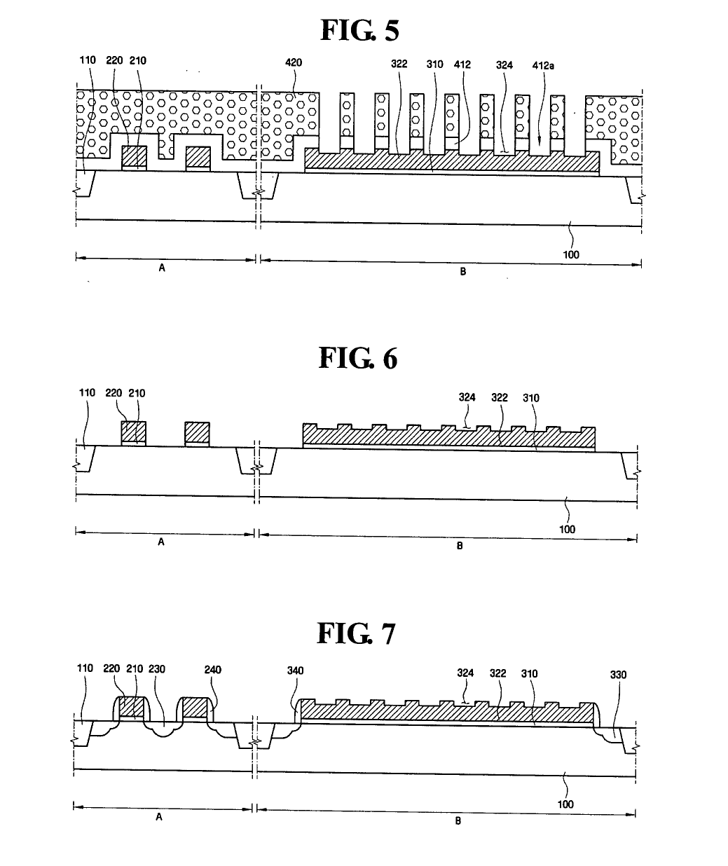

Next, with reference to FIGS. 1 and 5, a second gate electrode 322 may be formed by patterning the second gate electrode pattern 320 (see FIG. 4) (S140).

More particularly, e.g., in some embodiments of the invention, before the second gate electrode 322 is patterned, the hard mask 410 may be patterned using, e.g., the photoresist pattern 420 as an etching mask to form a hard mask pattern 412. As shown in FIG. 5, the hard mask pattern 412 may include opening(s) 412a. Portions of a top surface of the second gate electrode pattern 320 may be exposed through the opening(s) 412a of the hard mask pattern 412.

Next, the second gate electrode pattern 320 may be patterned using, e.g., the hard mask pattern 412 as an etching mask to form the second gate electrode 322. The second gate electrode pattern 320 may be etched by, e.g., dry etching. A number of recesses 324 may be formed on the top surface of the patterned second gate electrode 322. The recesses 324 may be formed in a direction along which the second gate electrode 322 extends, e.g., along a length direction of the second gate electrode 322.

In embodiments of the invention, by providing the recess(es) 324, a surface area of the second gate electrode 322 may be increased, and increasing the surface area of the second gate electrode 322, may be beneficial for a subsequent process silicidation process for forming silicide. However, in general, as a number of the recesses 324 increases, an interval between the recesses 324 decreases. The interval between the recesses 324 may be set so as to ensure that silicidation will occur during a subsequent silicidation process. In some embodiments of the invention, an interval between the recesses 324 may be equal to or about 400 Å or more because a width of at least 400 Å may better enable silicon and metal to react, e.g., fully react, with each other during a subsequent silicidation process. Thus, in some embodiments of the invention, a number of the recesses 324 that may be formed may be determined based on a minimum width for sufficient silicidation to occur, while increasing the surface area of the second gate electrode 322, e.g., maximizing the surface area of the second gate electrode 322 that may be subjected to silicidation. A depth of the recess(es) 324 may be, e.g., equal to or within a range of about 200 Å to about 500 Å. The depth of the recess(es) 324 may be determined based on a thickness of metal silicide to be formed during a subsequent silicidation process and a thickness of the second gate electrode 322.

Next, with reference to FIGS. 1 and 6, the photoresist pattern 420 (shown in FIG. 5) and the hard mask pattern 412 (shown in FIG. 5) may be removed (S150).

The photoresist pattern 420 may be removed by performing, e.g., an ashing process and a photoresist strip process (PR strip process). The hard mask pattern 412 may be removed by, e.g., wet etching.

Next, with reference to FIGS. 1 and 7, first and second spacers 240 and 340, and first and second source/drain regions 230 and 330 may be formed (S160).

More particularly, e.g., a light concentration ion implantation may be performed on the first and second regions A and B to form a lightly doped region of an LDD (Lightly Doped Drain) structure. In cases in which a transistor to be formed is an N-type transistor, N-type impurities may be implanted to form the N-type transistor. The N-type impurities may include, e.g., P or As, etc. In cases in which a transistor to be formed is a P-type transistor, P-type impurities may be implanted to form the P-type transistor. The P-type impurities may include, e.g., boron (B), boron fluoride (BF₂, BF₃), indium (In), etc.

Next, an insulating film may be conformally formed on the surface of the substrate 100, e.g., the entire top surface of the substrate 100, and an anisotropic etching may be performed thereon to form the first and second spacers 240 and 340 on side surfaces of the first and second gate electrodes 220 and 322, respectively.

Next, the first and second source/drain regions 230 and 330 may be formed by, e.g., implanting high concentration ions using the first and second gate electrodes 220 and 322 and the first and second spacers 240 and 340 as masks.

Next, with reference to FIGS. 1 and 8, impurities inside the first and second source/drain regions 230 and 330 may be activated by performing a thermal treatment on the substrate 100 in which the first and second source/drain regions 230 and 330 are formed. Next, the surface of the substrate 100 on which the first and second gate electrodes 220 and 322 and the first and second source/drain regions 230 and 330 are formed may be cleaned in order to remove natural oxide films and particles, etc. remaining on the surface of the substrate 100.

Additionally, with reference to FIGS. 1 and 8, a first metal silicide film 250 may be formed on a surface of the first source/drain region 230, and a second metal silicide film 350 may be formed on a surface of the second gate electrode 322 (S170).

More particularly, to form silicide films, e.g., the first metal silicide film 250 and the second metal silicide film 350, a metal film (not shown) for forming silicide may be formed on the surface of the substrate 100, e.g., the entire surface of the substrate 100, on which the first and second gate electrodes 220 and 322 and the first and second source/drain regions 230 and 330 are formed. The metal film for forming silicide may include, e.g., a low-resistance metal, such as titanium (Ti), tungsten (W), cobalt (Co), nickel (Ni), etc.

A thermal treatment process may then be performed on the substrate 100. The thermal treatment process may be performed using, e.g., an RTP (Rapid Thermal Process) device, a furnace, or the like. As the thermal treatment process is performed, metal and silicon may react with each other at portions where the metal film for forming silicide is in contact with silicon, and may thereby form metal silicide film(s). For example, the first metal silicide film 250 may be formed on the surface of the first source/drain region 230, and the second metal silicide film 350 may be formed on the surface of the second gate electrode 322. In addition, third and fourth metal silicide films 260 and 360 may be formed on the surface of the first gate electrode 220 and a surface of the second source/drain regions 330, respectively. The third and fourth metal silicide films 260 and 360 may be formed to have a thickness that is the same as or similar to a thickness of the first metal silicide film 250.

As discussed above, because a number of recesses 324 may be formed on the surface of the second gate electrode 322, the surface area of the second gate electrode 322 may be increased. Therefore, silicide reaction may be more likely to occur on the second gate electrode 322 including the recess(es) 324 than on a gate electrode not having reces(es) 324 formed thereon, e.g., the first gate electrode pattern 220. As a result of the recess(es) 324 of second gate electrode 322, the second metal silicide film 350 may have a larger thickness than the first metal silicide film 250 on the first gate electrode pattern 220.

Referring to FIG. 8, in some embodiments of the invention, the second metal silicide film 350 may have a wave-like or undulating step-like shape. That is, e.g., because the plurality of recesses 324 may be formed on the top surface of the second gate electrode 322, a plurality of recesses 324′ corresponding to the recesses 324 of the second gate electrode 322 may be formed in the first metal film (not shown) for forming the second metal silicide film 350. Further, as a result of the recesses 324′ of the second metal silicide film 350, a bottom surface of the second metal silicide film 350 may also have a wave-like or step-like shape in accordance with a shape and number of the recess(es) 324′. In some embodiments of the invention, an interval between the recess(es) 324′ on a top surface of the second metal silicide film 350 may be about 400 Å or more along a length direction of the second gate electrode 322. In some embodiments of the invention, a depth of the recess(es) 324′ may be equal to or within a range of about 200 Å to about 500 Å. A thickness of the second metal silicide film 350 may be larger than the depth of the recess(es) 324′.

Subsequently, a selective wet etching process may be performed to remove portions of the metal film (not shown) that has not reacted to form silicide.

Referring to FIG. 8, an exemplary embodiment of a semiconductor integrated circuit device employing one or more aspects of the invention will be described below.

Referring to FIG. 8, the semiconductor integrated circuit device may include the first transistor 200 and the second transistor 300. The first transistor 200 may be on the first region A, and the second transistor 300 may be on the second region B. Further, the substrate 100 on which the first and second transistors 200 and 300 may be formed may be divided into an active region and an inert region by the isolation film 110, e.g., an STI or an FOX.

The first transistor 200 may include the first gate insulating film 210, the first gate electrode 220, and the first source/drain region 230. The first transistor 200 may also include the first metal silicide film 250 and/or the third metal silicide film 260. The first source/drain region 230 may be formed in the substrate 100 in accordance with, e.g., the first spacer 240 and/or the first gate electrode 220, i.e., may be aligned with the first gate electrode 220 and/or the first spacer 240. The first metal silicide film 250 may be formed on the first gate electrode 220 and the third metal silicide film 260 may be formed on the first source/drain regions 230.

The first insulating film 210 may include, e.g., silicon oxide film that may be formed by, e.g., thermally oxidizing the substrate 100, SiON, GeₓO_{y}N_{z}, GeₓSi_{y}O_{z}, a high dielectric material, mixtures thereof, or a laminate thereof, in which they are sequentially laminated. The first gate electrode 220 may be a conductor, which may include polysilicon doped with impurities. A thickness of the first gate electrode 220 may be, e.g., about 2000 Å. The first source/drain region 230 may be formed to have an LDD structure.

The first metal silicide film 250 may be on the surface of the first gate electrode 220 and may have a uniform or substantially uniform thickness. The thickness of the first metal silicide film 250 may be, e.g., about 200 Å. The top surface of the first gate electrode 220 may be substantially flat, i.e. planar.

The third metal silicide film 260 may be on the surface of the first source/drain region. At a region(s) where the isolation film 110 contacts the first source/drain regions 230, the third metal silicide film 260 may have a larger thickness than other regions thereof. This is because small grooves 112 may be generated at a boundary between the isolation region 110 and the active region, e.g., the first source/drain regions 230, as a result of forming the isolation film 110 and/or a cleaning process. Because of the groove(s) 112, an amount of the first source/drain regions 230 exposed to an outside at the boundary region between the active region and the isolation region 110 may be more than that of other regions, e.g., a corresponding portion of the top surface of the first source/drain region 230 may be exposed in addition to a sidewall portion of the first source/drain region 230 while in other regions only a top surface thereof may be exposed. Therefore, more silicidation may occur at the boundary region between the active region and the isolation region, and thus, more silicide may be formed at the boundary region between the active region and the isolation region than at other regions. Therefore, as a result, the third metal silicide film 260 may have a uniform or substantially uniform first thickness at a first portion 260a thereof and a second thickness at a second portion 260b thereof, and the second thickness may be greater that the first thickness.

In some embodiments of the invention, an interval between a lower boundary of the third metal silicide film 260 and a lower boundary of the first source/drain region 230 may be, e.g., about 400 Å or more. For example, if a depth of the first source/drain region 230 is in a range of, e.g., about 1000 Å to about 1200 Å, the thickness of the third metal silicide film 260 at the second portion 260b of the third metal silicide film 260 may be equal to or within about 800 Å, e.g., at a region contacting the isolation region 110. More particularly, in some embodiments of the invention, the interval between the lower boundary of the third metal silicide film 260 and the first source/drain region 230 may be set to be at least about 400 Å because current may leak through a lower portion of the first source/drain region 230 if the interval between lower boundaries of the third metal silicide film 260 and the first source/drain region 230 is less than about 400 Å.

While FIG. 8 illustrates exemplary first and third metal silicide films 250, 260, embodiments of the invention are not limited thereto. For example, in some embodiments of the invention, the first metal silicide film 250 may not be formed on the first gate electrode 220, e.g., in cases in which the hard mask 410 or the like is formed on the first gate electrode 220.

The second transistor 300 may include the second gate insulating film 310, the second gate electrode 322, and the second source/drain regions 330. The second transistor 300 may also include the second metal silicide film 350 and/or the fourth metal silicide film 330. The second source/drain regions 330 may be formed in the substrate 100 in accordance with, e.g., the second spacer 340 and/or the second gate electrode 322, i.e., may be aligned with the second gate electrode 322 and/or the second spacer 340. The second metal silicide film 350 may be formed on the surface of the second gate electrode 322. The second metal silicide film 350 may have, e.g., a wave-like or undulating step-like shape and/or a thickness of the second metal silicide film 350 may be larger than a thickness of the first metal silicide film 250.

In some embodiments of the invention, e.g., silicon oxide film which is formed by thermal oxidation of the substrate 100, SiON, GeₓO_{y}N_{z}, GeₓSi_{y}O_{z}, a high dielectric material, mixtures thereof, or a laminate thereof, in which they are sequentially laminated may be used as the second gate insulating film 310. The second gate electrode 322 may be a conductor, which may include, e.g., polysilicon doped with impurities. A thickness of the second gate electrode 322 may be, e.g., about 2000 Å. The second source/drain regions 330 may be formed to have an LDD structure.

The second metal silicide film 350 formed on the surface of the second gate electrode 322 may have a larger thickness than the first metal silicide film 250 formed on the first gate electrode 220, as a result of, e.g., the recesses 324 that may be formed in the second gate electrode 322. For example, if the first metal silicide film 250 has a thickness of about 200 Å, the second metal silicide film 350 may have a thickness equal to or within a range of about 400 Å to about 450 Å. In some embodiments of the invention, the recesses 324′ of the second metal silicide film 350 may have a depth equal to or within a range of about 100 Å to about 300 Å.

The fourth metal silicide film 360 may be formed on the surface of the second source/drain regions 330. Although FIG. 8 illustrates the second and fourth metal silicide films 350 and 360, embodiments of the invention are not limited thereto. For example, in some embodiments of the invention, the fourth metal silicide film 360 may not be formed, e.g., in embodiments in which a silicide blocking film is formed on the second source/drain regions 330.

In the semiconductor integrated circuit device according to the exemplary embodiment of the invention, the thickness of the second metal silicide film 350 formed on the second gate electrode 322 of the second transistor 300 may be larger than that of other metal silicide films formed in other regions, e.g., the first metal silicide film 250. In other words, it is possible to form a metal silicide film having a larger thickness on one or more regions of the substrate and metal silicide film(s) having relatively smaller thickness(es) on other regions of the substrate. Thus, embodiments of the invention enable a thickness of a respective metal silicide film to be controlled in accordance with a resistance of the respective region, e.g., increase a thickness of the metal silicide film to reduce resistance. For example, in region(s) where a thickness of the metal silicide may cause an increase in leakage current, e.g., in a case of the smaller sized transistor and/or on source/drain regions, the respective metal silicide film may be formed with a relatively small thickness, thereby reducing and/or preventing leakage current.

Embodiments of the invention may provide a semiconductor integrated circuit device having improved characteristics by providing a more reliable semiconductor device therein, which may include low resistance elements, by forming metal silicides having different thicknesses in respective semiconductor devices based on characteristics of the respective semiconductor devices.

Embodiments of the invention may enable a metal silicide film having a larger thickness to be selectively formed on, e.g., transistor(s) requiring low resistance in which metal silicide should be formed with a large thickness, while separately enabling a metal silicide film having a relative smaller thickness to be selectively formed on, e.g., transistor(s) that are more prone to leakage current, e.g., smaller semiconductor devices and/or on source/drain regions.

Embodiments of the invention may separately provide semiconductor integrated circuit device having improved characteristics because a more reliable semiconductor device can be formed therein, e.g., by forming metal silicides having different thickness(es) in the respective transistors in accordance with the characteristics, e.g., size, resistance or portion, of the semiconductor device.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor integrated circuit device, the method comprising:
forming a first gate insulating film and a first gate electrode on a first region of a substrate, and forming a second gate insulating film and a second gate electrode on which a plurality of recesses are formed on a second region of the substrate;
forming first and second source/drain regions in the substrate, the first and second source/drain regions being aligned with the first and second gate electrodes, respectively; and
forming a first metal silicide film and a second metal silicide film on the first and second source/drain regions and the second gate electrode, respectively, wherein the second metal silicide film is thicker than the first metal silicide film and a cross-sectional shape of the second metal silicide film is wave shaped.

2. The method as claimed in claim 1, wherein forming the second gate electrode comprises:
forming a second gate electrode pattern on the second gate insulating film;
forming a hard mask on the substrate;
patterning a top surface of the second gate electrode pattern using the hard mask as an etching mask to form the second gate electrode including the plurality of recesses; and
removing the hard mask.

3. The method as claimed in claim 2, wherein the hard mask includes SiON.

4. The method as claimed in claim 1, wherein defining the first region and the second region includes:
forming an isolation region in the substrate, and an interval between a lower boundary of the first metal silicide and a lower boundary of the source/drain region is about 400 Å or more at a region where the isolation region contacts the first source/drain region.

5. The method as claimed in claim 1, further comprising forming a third metal silicide film on a surface of the first gate electrode while forming the first metal silicide film and the second metal silicide film.

6. The method as claimed in claim 1, wherein forming the first metal silicide film and the second metal silicide film comprises forming a metal film on the substrate and thermally treating the substrate.

7. A semiconductor integrated circuit device, comprising:
a first transistor on a first region of a substrate, the first transistor including a first gate insulating film, a first gate electrode, first source/drain regions aligned with the first gate electrode, and a first metal silicide film on a surface of the first source/drain region, the first metal silicide film having a first thickness; and
a second transistor on a second region of the substrate, the second transistor including a second gate insulating film, a second gate electrode, second source/drain regions aligned with the second gate electrode, and a second metal silicide film on a surface of the second gate electrode, the second metal silicide film having a second thickness that is larger than the first thickness and having a cross-sectional shape that is wave shaped.

8. The semiconductor integrated circuit device as claimed in claim 7, wherein a top surface of the second metal silicide film includes a plurality of recesses.

9. The semiconductor integrated circuit device as claimed in claim 8, wherein the second thickness of the second metal silicide film is larger than a depth of the recesses.

10. The semiconductor integrated circuit device as claimed in claim 8, wherein an interval between the plurality of recesses is about 400 Å or more.

11. The semiconductor integrated circuit device as claimed in claim 8, wherein the plurality of recesses are arranged along a direction along which the second gate electrode extends.

12. The semiconductor integrated circuit device as claimed in claim 7, further comprising an isolation region at one side of the first source/drain region,
wherein at a region where the isolation region contacts the first source/drain region, an interval between a lower boundary of the first metal silicide film and a lower boundary of the respective first source/drain region is about 400 Å or more.

13. The semiconductor integrated circuit device as claimed in claim 7, wherein the first region is a cell region, and the second region is a core/peri region.

14. The semiconductor integrated circuit device as claimed in claim 7, wherein the second transistor is a device having less resistance than the first transistor.

15. The semiconductor integrated circuit device as claimed in claim 7, wherein the first and second silicide films include at least one of titanium (Ti), tungsten (W), cobalt (Co), and nickel (Ni).

16. The semiconductor integrated circuit device as claimed in claim 7, wherein a third metal silicide film is disposed on a surface of the first gate electrode.

17. The semiconductor integrated circuit device as claimed in claim 7, wherein a fourth metal silicide film is disposed on a surface of the second source/drain regions.

18. The semiconductor integrated circuit device as claimed in claim 16, wherein the third metal silicide film has a uniform or substantially uniform thickness.

19. The semiconductor integrated circuit device as claimed in claim 17, further comprising an isolation region at one side of each of the first and second source/drain regions, wherein the thickness of the first metal silicide film and a thickness of the fourth metal silicide film is larger at a region where the respective isolation region contacts the first and second source/drain region regions, respectively, than at a region of the first and second source/drain region closer to the first and second gate electrodes, respectively.

20. A semiconductor integrated circuit device, comprising:
a first transistor on a first defined region of a substrate, the first transistor including first source/drain regions, a first gate insulating film and a first gate electrode, the first gate electrode having a substantially flat top surface;
a second transistor on a second defined region of the substrate, the second transistor including second source/drain regions, a second gate insulating film and a second gate electrode, the second gate electrode having a plurality recesses on a top surface thereof,
at least one of a first metal silicide film on the first gate electrode and a second metal silicide film on the first and second source/drain regions, the first metal silicide film and the second metal silicide film having a substantially flat top surface; and
a third metal silicide film on the second gate electrode, the third metal silicide film having a plurality of recesses on a top surface thereof corresponding to the plurality of recesses on the top surface of the second gate insulating film.

21. The semiconductor integrated circuit device as claimed in claim 20, wherein the third metal silicide film has a greater thickness than the first metal silicide film and/or the second metal silicide film.
